(19) United States
(12) Patent Application Publication
(10) Pub. No.: US 2026/0148776 A1
(43) Pub. Date: May 28, 2026

(54) MEMORY DEVICE AND OPERATING METHOD OF THE MEMORY DEVICE

(71) Applicant: SK hynix Inc., Gyeonggi-do (KR)

(72) Inventor: Hee Youl LEE, Gyeonggi-do (KR)

(21) Appl. No.: 19/218,370

(22) Filed: May 26, 2025

(30) Foreign Application Priority Data
Nov. 28, 2024 (KR) 10-2024-0173456

(51) Int. Cl. G11C 16/34; G11C 16/04; G11C 16/26

(52) U.S. Cl. CPC G11C 16/3427; G11C 16/0483; G11C 16/26; G11C 16/3445; G11C 16/3459

(57) ABSTRACT

A memory device and a method of operating the memory device are provided. The memory device may include a plurality of memory blocks, an operating voltage generating circuit configured to generate and apply an operating voltage to global word lines, a plurality of pass transistor units respectively corresponding to the plurality of memory blocks, respectively configured to couple local word lines of the plurality of memory blocks to the global word lines, and a well bias applying circuit configured to apply a well bias having a negative level to a well of a plurality of pass transistors included in each of the plurality of pass transistor units.

### CROSS-REFERENCE TO RELATED APPLICATION

The present application claims priority under 35 U.S.C. § 119(a) to Korean patent application number 10-2024-0173456 filed on Nov. 28, 2024, the entire disclosure of which is incorporated herein by reference.

### BACKGROUND

### 1. Technical Field

Various embodiments of the present disclosure generally relate to an electronic device, more particularly, to a memory device and a method of operating the memory device.

### 2. Related Art

Memory devices may include non-volatile memory devices that retain stored data even in the absence of power supply. The non-volatile memory devices may be divided into two-dimensionally structured memory devices or three-dimensionally structured memory devices, depending on arrangements of memory cells of each of the non-volatile memory devices. Memory cells of a non-volatile memory device having a two-dimensional structure may be arranged in a single layer on a substrate. Memory cells of a non-volatile memory device having a three-dimensional structure may be stacked in a vertical direction to the substrate. Since integration density of the non-volatile memory device having the three-dimensional structure is greater than that of the non-volatile memory device having the two-dimensional structure, electronic devices including three-dimensionally structured non-volatile memory devices have recently been increasing.

### SUMMARY

Various embodiments of the present disclosure are directed to a memory device capable of improving reliability of the memory device by suppressing a level change of an operating voltage applied to a selected word line due to word line noise and a method of operating the memory device.

According to an embodiment of the present disclosure, a memory device may include a memory cell array including a plurality of memory blocks, an operating voltage generating circuit configured to generate and apply an operating voltage to global word lines, a plurality of pass transistor units respectively corresponding to the plurality of memory blocks, respectively configured to couple local word lines of the plurality of memory blocks to the global word lines, and a well bias applying circuit configured to apply a well bias having a negative level to a well of a plurality of pass transistors included in each of the plurality of pass transistor units when a read voltage, a program verify voltage, or an erase verify voltage to be applied to a selected memory block among the plurality of memory blocks in a read operation, a program verify operation, or an erase verify operation is lower than a set voltage.

According to an embodiment of the present disclosure, a method of operating a memory device may include comparing a level of a set voltage with a read voltage to be applied to a selected memory block when performing a read operation, setting a well bias applied to a well of pass transistors corresponding to the selected memory block and an unselected memory block to a first level when the level of the read voltage is lower than the level of the set voltage, setting the well bias applied to the well of the pass transistors corresponding to the selected memory block and the unselected memory block to a second level greater than the first level when the level of the read voltage is equal to or greater than the level of the set voltage, and applying the read voltage to a selected local word line of the selected memory block and applying the well bias having the first level or the second level to the well of the pass transistors.

According to an embodiment of the present disclosure, a method of operating a memory device may include setting an order of applying a plurality of read voltages to a selected memory block to a descending order or an ascending order when performing a read operation, setting a well bias to be applied to a well of pass transistors corresponding to the selected memory block and an unselected memory block to a first level when the order is set to the descending order, setting the well bias to be applied to the well of the pass transistors corresponding to the selected memory block and the unselected memory block to a second level greater than the first level when the order of applying the plurality of read voltages is set to the ascending order, and sequentially applying the plurality of read voltages to a selected local word line of the selected memory block in the set descending or ascending order, and applying the well bias having the first level or the second level to the well of the pass transistors.

### BRIEF DESCRIPTION OF THE DRAWINGS

FIG. 1 is a diagram illustrating a memory device according to an embodiment of the present disclosure;

FIG. 2 is a diagram illustrating a memory cell array, a voltage generating circuit, and an address decoder of FIG. 1;

FIG. 3 is a diagram illustrating a first memory block and a first pass transistor unit of FIG. 2;

FIG. 4 is a cross-sectional view of the memory device for illustrating the pass transistor of FIG. 3;

FIG. 5 is a flowchart illustrating a method of operating the memory device according to an embodiment of the present disclosure;

FIG. 6 is a flowchart illustrating a method of operating the memory device according to another embodiment of the present disclosure;

FIG. 7 is a flowchart illustrating a method of operating the memory device according to another embodiment of the present disclosure;

FIG. 8 is a flowchart illustrating a method of operating the memory device according to another embodiment of the present disclosure;

FIG. 9 is a flowchart illustrating a method of operating the memory device according to another embodiment of the present disclosure;

FIG. 10 is a block diagram illustrating a configuration of a memory system according to an embodiment of the present disclosure;

FIG. 11 is a block diagram illustrating a configuration of the memory system according to another embodiment of the present disclosure;

FIG. 12 is a block diagram illustrating a configuration of a computing system according to an embodiment of the present disclosure; and

FIG. 13 is a block diagram illustrating the computing system according to an embodiment of the present disclosure.

### DETAILED DESCRIPTION

Specific structural or functional descriptions disclosed herein are merely illustrative for the purpose of describing embodiments according to the concept of the present disclosure. Embodiments according to the concept of the present disclosure may be implemented in various forms and should not be construed as being limited to the specific embodiments set forth herein.

Hereinafter, embodiments of the present disclosure will be described in detail with reference to the accompanying drawings in order for those skilled in the art to be able to implement the technical spirit of the present disclosure.

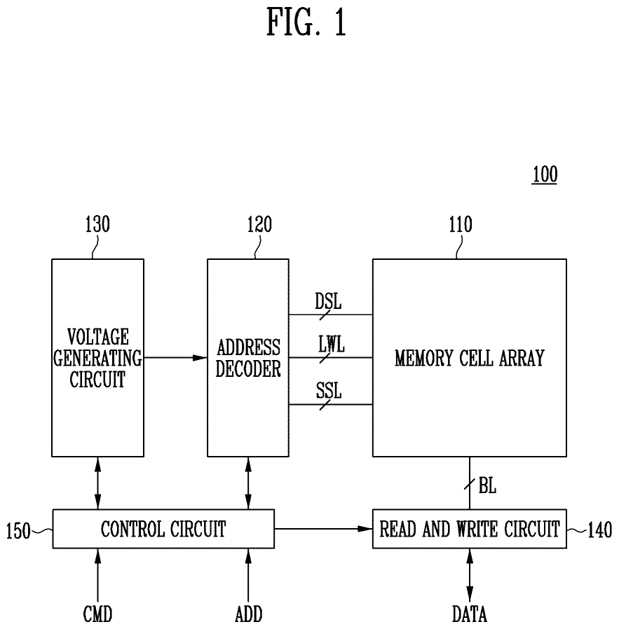

FIG. 1 is a diagram illustrating a memory device 100 according to an embodiment of the present disclosure.

Referring to FIG. 1, the memory device 100 may include a memory cell array 110, an address decoder 120, a voltage generating circuit 130, a read and write circuit 140, and a control circuit 150.

The memory cell array 110 may include memory cells. In an embodiment, the memory cell array 110 may include memory blocks, and each of the memory blocks may include pages. The memory block may be a unit of an erase operation, and the page may be a unit of a read operation. The memory cell array 110 may be coupled to the address decoder 120 through a row line such as a source select line SSL, a plurality of local word lines LWL, and a drain select line DSL. The memory cell array 110 may be coupled to the read and write circuit 140 through a column line such as a bit line BL.

The control circuit 150 may receive a command CMD and an address ADD from a controller. The control circuit 150 may generate a control signal to perform an internal operation such as a program operation, a read operation, and an erase operation according to the received command CMD. The control circuit 150 may output a control signal to the voltage generating circuit 130, the address decoder 120, and the read and write circuit 140.

The voltage generating circuit 130 may generate operating voltages of various voltage levels for performing an internal operation, and may provide the generated operating voltages to the address decoder 120. The operating voltage may be an operating voltage for performing a program operation, a read operation, an erase operation, or the like. The operating voltage may include a well bias to supply to a well region of a pass transistor included in the address decoder 120. The operating voltages may have a positive level or the negative level.

In an embodiment, the voltage generating circuit 130 may generate a program voltage, a pass voltage, and a program verify voltage for performing a program operation. The voltage generating circuit 130 may generate a read voltage, and a pass voltage for performing a read operation. The program verify voltage or the read voltage may have a voltage level that turns the memory cell on or off according to a program state of the selected memory cell. The pass voltage may have a voltage level that turns the memory cell on regardless of the program state of the memory cell. The voltage generating circuit 130 may generate an erase voltage and an erase verify voltage performing an erase operation. The voltage generating circuit 130 may generate the well bias for controlling a voltage level of the well region of the pass transistor included in the address decoder 120 when performing an erase verify operation among a program verify operation, a read operation, or an erase verify operation of a program operation. For example, the voltage generating circuit 130 may generate the well bias having the negative level during the program verify operation using the program verify voltage at a level lower than a set voltage, and generate the well bias having a ground voltage or the positive level during the program verify operation using the program verify voltage at a level equal to or greater than the set voltage.

In addition, the voltage generating circuit 130 may generate the well bias having the negative level during the read operation using the read voltage at a level lower than the set voltage, and generate the well bias with the ground voltage or the positive level during the read operation using the read voltage at the level equal to or greater than the set voltage.

In addition, the voltage generating circuit 130 may generate the well bias having the negative level when sequentially applying a plurality of program verify voltages or a plurality of read voltages in a descending order from a voltage having a high potential to a voltage having a low potential during the program verify operation or the read operation, and may generate the well bias having the ground voltage or the positive level when sequentially applying the plurality of program verify voltages or the plurality of read voltages in an ascending order from the voltage having the low potential to the voltage having the high potential.

In addition, the voltage generating circuit 130 may generate the well bias having the negative level during the erase verify operation using the erase verify voltage having the level lower than the set voltage, and may generate the well bias having the ground voltage or the positive level during the erase verify operation using the erase verify voltage having the level equal to or greater than the set voltage.

The address decoder 120 may activate the source select line SSL, the local word line LWL, or the drain select line DSL according to the address. For example, the address decoder 120 may switch a global line coupled to the voltage generating circuit 130 and the source select line SSL, the local word line LWL, and the drain select line DSL coupled to the memory cell array 110 to transfer the operating voltages received through the global line to the source select line SSL, the local word line LWL, and the drain select line DSL.

The read and write circuit 140 may be coupled to the memory cell array 110 through the bit lines BL. During the program operation, the read and write circuit 140 may operate as a write driver, and may input data to be stored in the memory cell array 110. In the read or verify operation, the read and write circuit 140 may operate as a sense amplifier and may output data stored in the memory cell array 110.

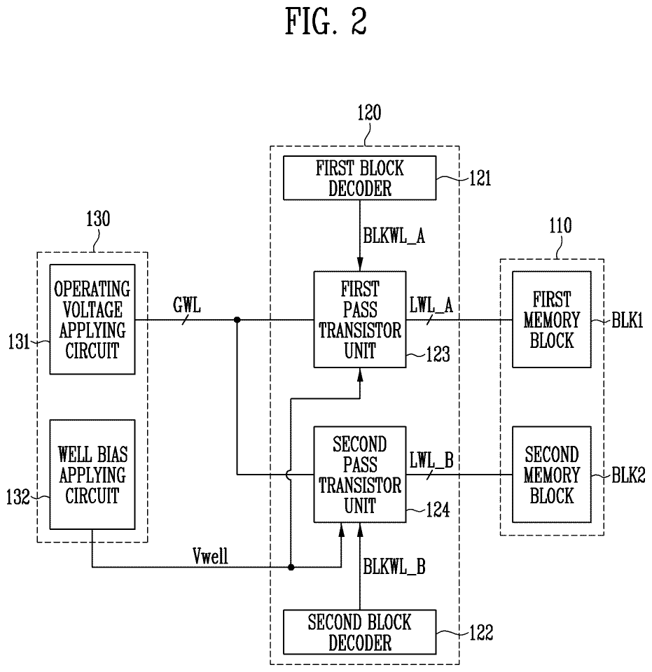

FIG. 2 is a diagram illustrating the memory cell array 110, the voltage generating circuit 130, and the address decoder 120 of FIG. 1.

Referring to FIG. 2, the memory cell array 110 may include a first memory block BLK1 and a second memory block BLK2. The memory cell array 110 may include at least two or more memory blocks.

The first memory block BLK1 may be coupled to first local word lines LWL_A, and the second memory block BLK2 may be coupled to second local word lines LWL_B.

The address decoder 120 may include a first block decoder 121, a second block decoder 122, a first pass transistor unit 123, and a second pass transistor unit 124.

Each of the first block decoder 121 and the first pass transistor unit 123 may correspond to the first memory block BLK1, and each of the second block decoder 122 and the second pass transistor unit 124 may correspond to the second memory block BLK2.

When the address corresponding to the first memory block BLK1 is received, the first block decoder 121 may activate and output a first block select signal BLKWL1 at a high potential. The first pass transistor unit 123 may switch the global word lines GWL and the first local word lines LWL_A to be coupled to each other in response to the first block select signal BLKWL1 activated at the high potential. Accordingly, the operating voltages received through the global word lines GWL may be transmitted to the first local word lines LWL_A.

When the address corresponding to the second memory block BLK2 is received, the second block decoder 122 may activate and output a second block select signal BLKWL2 at a high potential. The second pass transistor unit 124 may switch the global word lines GWL and the second local word lines LWL_B to be connected to each other in response to the second block select signal BLKWL2 activated at the high potential. Accordingly, the operating voltages received through the global word lines GWL may be transmitted to the second local word lines LWL_B.

The first pass transistor unit 123 may include a plurality of pass transistors, and the plurality of pass transistors may switch the global word lines GWL and the first local word lines LWL_A. The second pass transistor unit 124 may include the plurality of pass transistors, and the plurality of pass transistors may switch the global word lines GWL and the second local word lines LWL_B.

The voltage generating circuit 130 may include an operating voltage applying circuit 131 and a well bias applying circuit 132. The operating voltage applying circuit 131 may generate the operating voltage required for the program operation, the read operation, and the erase operation of the memory cells, and may transmit the generated operating voltage to the global word lines GWL. In an embodiment, during the program voltage applying operation of the program operation, the operating voltage applying circuit 131 may transmit the program voltage or the pass voltage to the global word lines GWL. During the program verify operation of the program operation, the operating voltage applying circuit 131 may transmit the program verify voltage or the pass voltage to the global word lines GWL. During the read operation, the operating voltage applying circuit 131 may transmit the read voltage or the pass voltage to the global word lines GWL. During the erase verify operation of the erase operation, the operating voltage applying circuit 131 may transmit the erase verify voltage to the global word lines GWL.

The well bias applying circuit 132 may generate a well bias Vwell, and may apply the generated well bias Vwell to the well region of the first pass transistor unit 123 and the second pass transistor unit 124.

The well bias applying circuit 132 may generate the well bias Vwell having various levels according to the level of the voltage applied to the selected word line of the selected memory block during the program verify operation, the read operation, or the erase verify operation. For example, when the program verify voltage applied to the selected word line of the selected memory block during the program verify operation is at the level lower than the set voltage, the well bias applying circuit 132 may generate the well bias Vwell having the negative level, and may generate the ground voltage or the well bias having the positive level when the program verify voltage is at the level equal to or greater than the set voltage.

In addition, when the read voltage applied to the selected word line of the selected memory block during the read operation is at the level lower than the set voltage, the well bias applying circuit 132 may generate the well bias Vwell having the negative level, and when the read voltage is at the level greater than or equal to the set voltage, the well bias applying circuit 132 may generate the well bias Vwell having the ground voltage or the positive level.

In addition, when the erase verify voltage applied to the selected word line of the selected memory block during the erase verify operation is at the level lower than the set voltage, the well bias applying circuit 132 may generate the well bias Vwell having the negative level, and may generate the ground voltage or the well bias having the positive level when the verify voltage is at the level equal to or greater than the set voltage.

In addition, the well bias applying circuit 132 may generate the well bias Vwell having the negative level when sequentially applying the plurality of program verify voltages or the plurality of read voltages in the descending order from a voltage having a high potential to a voltage having a low potential during the program verify operation or a read operation, and generate the well bias Vwell having the ground voltage or the positive level when sequentially applying the plurality of program verify voltages or the plurality of read voltages in an ascending order from the voltage having the low potential to the voltage having the high potential.

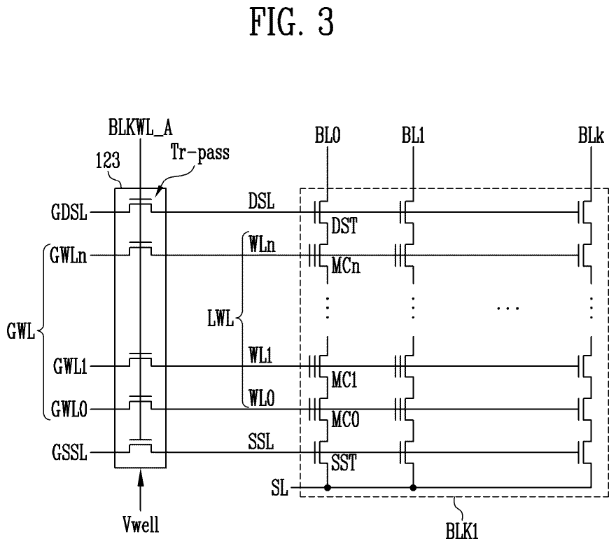

FIG. 3 is a diagram illustrating the first memory block BLK1 and the first pass transistor unit 123 of FIG. 2.

The first memory block BLK1 and the second memory block BLK2 in FIG. 2 may have similar structures to each other, and the first pass transistor unit 123 and the second pass transistor unit 124 may have similar structures to each other.

The first memory block BLK1 may include memory strings ST0 to STk coupled between bit lines BL0 to BLk and a source line SL, where k may be an integer greater than or equal to 1. Each of the memory strings ST0 to STk may include at least one drain select transistor DST, a plurality of memory cells MC0 to MCn, and at least one source select transistor SST, where n may be an integer greater than or equal to 1. The memory cells MC0 to MCn may be coupled to local word lines WL0 to WLn LWL. The source select transistor SST may control the connection between the memory strings ST0 to STk and the source line SL, and the drain select transistor DST may control the connection between the memory strings ST0 to STK and the bit lines BL0 to BLk. A gate of the source select transistor SST may be coupled to the source select line SSL, and a gate of the drain select transistor DST may be coupled to the drain select line DSL.

The first pass transistor unit 123 may include a plurality of pass transistors Tr_pass. The plurality of pass transistors Tr_pass may control connections between a global drain select line GDSL, the global word lines GWL, and the global source select line GSSL and the drain select line DSL, the local word lines LWL, and the source select line SSL. For example, the plurality of pass transistors Tr_pass may electrically couple the global drain select line GDSL and the drain select line DSL in response to the first block select signal BLKWL_A, electrically couple the global word lines GWL and the local word lines LWL, and electrically couple the global source select line GSSL and the source select line SSL.

The well bias Vwell may be applied to the well region of a semiconductor substrate in which the plurality of pass transistors Tr_pass are disposed. The well bias Vwell may have the negative level, the ground level, or the positive level.

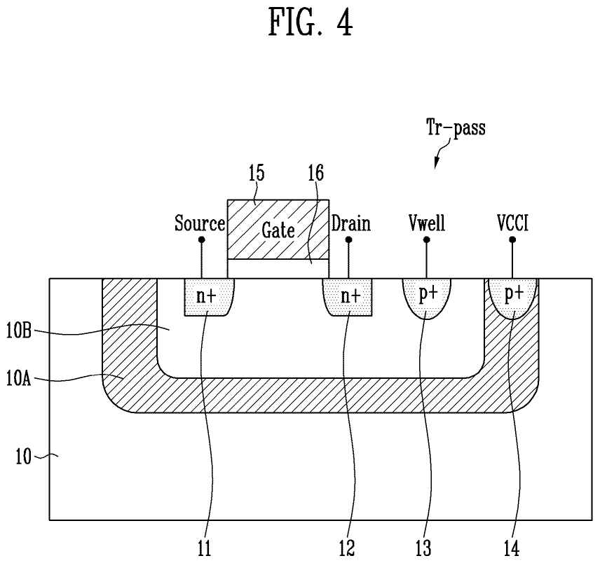

FIG. 4 is a cross-sectional view of the memory device for illustrating the pass transistor Tr_pass of FIG. 3.

Referring to FIG. 4, the memory device may include the pass transistor Tr_pass. The pass transistor Tr_pass may be located over a substrate 10 including a triple well. The triple well may be located in the substrate 10 and may include a first well region 10A and a second well region 10B that include different types of impurities. The substrate 10 may be a semiconductor substrate including p-type or n-type impurities. The first well region 10A may be located in the substrate 10 and may include a different type of impurity than the substrate 10. The second well region 10B may be located within the first well region 10A and may include a different type of impurity than the first well region 10A. In an embodiment, the substrate 10 may comprise p-type impurities, the first well region 10A may comprise n-type impurities, and the second well region 10B may comprise p-type impurities. The first well region 10A may be a deep n-well and the second well region 10B may be a p-well.

The pass transistor Tr_pass may include a gate electrode 15, a gate insulating layer 16, a first junction 11, and a second junction 12. The gate electrode 15 may be located over the substrate 10, and the gate insulating layer 16 may be located between the gate electrode 15 and the substrate 10. The first junction 11 and the second junction 12 may be located in the second well area 10B. The first junction 11 and the second junction 12 may include a different type of impurity than the second well region 10B. In an embodiment, the first junction 11 and the second junction 12 may include a n-type impurity at a high concentration.

The first junction 11 may be a source region and the second junction 12 may be a drain region. The first junction 11 may be coupled to one of the global lines including the global word lines, the global drain select line and the global source select line, and the second junction 12 may be coupled one of the local lines including the local word lines, the drain select line and the source select line. In another embodiment, the first junction 11 may be coupled to one of the local lines, and the second junction 12 may be coupled to one of the global lines.

The memory device may further include a third junction 13 and a fourth junction 14. The third junction 13 may include the same type of impurity with the second well region 10B at a high concentration. The third junction 13 may include a p-type impurity at a high concentration. The third junction 13 may be coupled to the well bias applying circuit 234, and the well bias Vwell may be applied to the second well region 10B through the third junction 13.

The fourth junction 14 may be located in the first well region 10A and may include the same type of impurity with the first well region 10A at a high concentration. The fourth junction 14 may include the n-type impurity at the high concentration. A power supply voltage VCCI may be applied to the fourth junction 14.

The program verify voltage, the read voltage, or the erase verify voltage may be applied to a selected local word line of the selected memory block during the program verify operation, the read operation, or the erase verify operation of the memory device, and the pass transistors corresponding to an unselected memory block are turned off so that the local word lines coupled to the unselected memory block are in a floating state. A voltage of 0 V is applied to the gates of the pass transistors corresponding to the unselected memory block, and the local word lines coupled to the unselect memory block may be floated to have a potential (e.g., VCC-Vt) greater than the set voltage. In this case, when the program verify voltage, the read voltage, or the erase verify voltage applied to the global word line is lower than the set voltage, the potential of the global word line may be increased by the potential of the local word line, so that the reliability of the program verify operation, the read operation, or the erase verify operation may be degraded. In the embodiments of the present disclosure, during the program verify operation, the read operation, or the erase verify operation, a well bias Vwell having the negative level is applied to the well region of the pass transistors corresponding to the selected memory block and the unselected memory blocks in a section in which the program verify voltage, the read voltage, or the erase verify voltage lower than a set voltage is applied to the local word line of the selected memory block, to prevent abnormal turn on of the pass transistor, thereby preventing the potential of the global word line from rising.

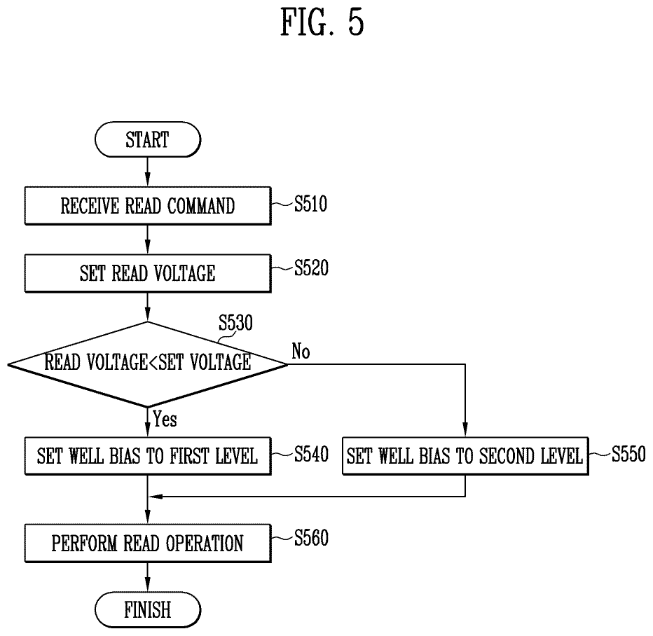

FIG. 5 is a flowchart illustrating a method of operating the memory device 100 according to an embodiment of the present disclosure.

The method of operating the memory device 100 according to an embodiment of the present disclosure will be described below with reference to FIGS. 1 to 5.

In operation S510, the memory device 100 may receive a read command. In an embodiment, the command CMD and the address ADD corresponding to the read operation may be received from the controller (not shown) outside the memory device 100.

In operation S520, the control circuit 150 may set the read voltage to be used in the read operation in response to the command CMD. The set read voltage may be one of the plurality of read voltages respectively corresponding to the plurality of program states of memory cells included in the selected memory block (e.g., the first memory block BLK1).

In operation S530, the control circuit 150 may determine whether the set read voltage has a potential lower than the set voltage.

In the operation S530, when it is determined that the set read voltage is lower than the set voltage (if YES), in operation S540, the control circuit 150 may set the well bias Vwell applied to the wells of the pass transistors Tr_pass included in the first pass transistor unit 123 and the second pass transistor unit 124 included in the address decoder 120 to the first level, and may control the voltage generating circuit 130 to generate the well bias VWell having the first level. The first level may be the negative voltage level.

In the operation S530, when it is determined that the set read voltage is equal to or greater than the set voltage (if NO), in operation S550, the control circuit 150 may set the well bias Vwell applied to the well of the pass transistors Tr_pass included in the first pass transistor unit 123 and the second pass transistor unit 124 included in the address decoder 120 to the second level, and may control the voltage generating circuit 130 to generate the well bias Vwell having the second level. The second level is greater than the first level and may be the ground or the positive voltage level.

In operation S560, the read operation is performed on the selected memory block (e.g., the first memory block BLK1).

The operating voltage applying circuit 131 of the voltage generating circuit 130 may generate a set read voltage and the pass voltage to transfer to the global word lines GWL. In addition, the well bias applying circuit 132 of the voltage generating circuit 130 may generate and output the well bias Vwell having the first level or the second level set in the operation S540 or the operation S550.

The first block decoder 121 of the address decoder 120 may generate and output the first block select signal BLKWL1 having the high potential, and the pass transistors TR_pass of the first pass transistor unit 123 may couple the global word lines GWL and the first local word lines LWL_A of the first memory block BLK1 in response to the first block select signal BRKWL1. Accordingly, the read voltage is applied to the selected local word line among the first local word lines LWL_A, and the pass voltage is applied to the remaining unselected local word lines.

The well bias Vwell having the first level or the second level may be applied to the wells of the pass transistors Tr_pass included in the first pass transistor unit 123 and the second pass transistor unit 124 of the address decoder 120, and when the read voltage is lower than the set voltage, the pass transistors Vwell of the second pass transistor unit 124 corresponding to the unselected memory block (e.g., the second memory block BLK2) may be prevented from being turned on abnormally by the well bias Vwell having the first level, thereby blocking the potential of the global word line from rising due to the potential of the local word line of the unselected memory block.

The read and write circuit 140 may sense a potential or an amount of current of the bit lines BL BL0 to BLk, the read data stored in the memory cells coupled to the selected local word line of the selected first memory block BLK1, and may output the read data DATA to the outside.

Although the read operation using one read voltage is illustrated in an embodiment of the present disclosure, when the read operation is performed using the plurality of read voltages, the operations S520 to S560 may be re-performed a plurality of times.

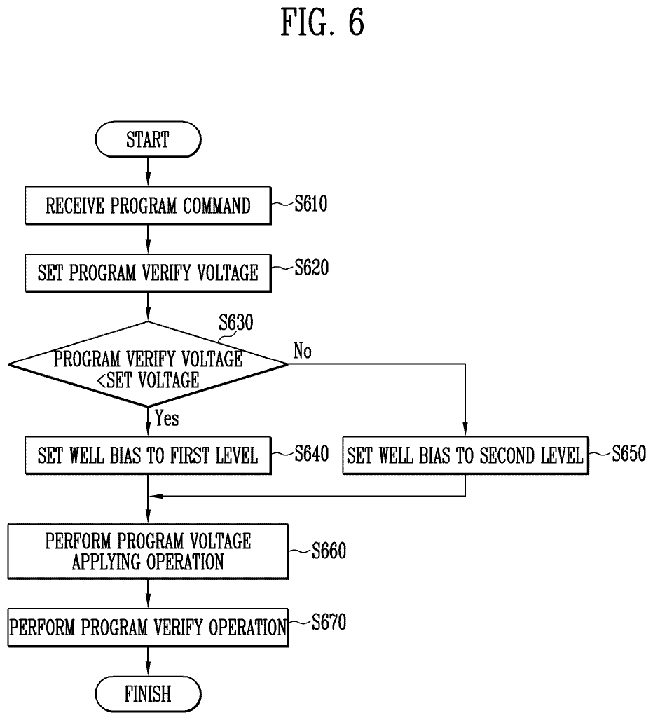

FIG. 6 is a flowchart illustrating a method of operating the memory device 100 according to another embodiment of the present disclosure.

The method of operating the memory device 100 according to another embodiment of the present disclosure will be described below with reference to FIGS. 1 to 4 and 6.

In operation S610, the memory device 100 may receive a program command. In an embodiment, the command CMD, the address ADD, and the data DATA corresponding to the program operation may be received from the controller (not shown) outside the memory device 100.

The read and write circuit 140 may apply a program allowable voltage (e.g., the ground voltage) or a program inhibit voltage (e.g., the power supply voltage VCCI) to the bit lines BL0 to BLk based on the received data DATA.

In operation S620, the control circuit 150 may set the program verify voltage to be used during the program verify operation during the program operation in response to the command CMD.

In operation S630, the control circuit 150 may determine whether the set program verify voltage has a potential lower than the set voltage.

In the operation S630, when it is determined that the set program verify voltage is lower than the set voltage (if YES), in operation S640, the control circuit 150 may set the well bias Vwell applied to the wells of the pass transistors Tr_pass included in the first pass transistor unit 123 and the second pass transistor unit 124 included in the address decoder 120 to the first level, and may control the voltage generating circuit 130 to generate the well bias VWell of the first level. The first level may be the negative voltage level.

In the operation S630, when it is determined that the set program verify voltage is equal to or greater than the set voltage (if NO), in operation S650, the control circuit 150 may set the well bias Vwell applied to the wells of the pass transistors Tr_pass included in the first pass transistor unit 123 and the second pass transistor unit 124 included in the address decoder 120 to the second level, and may control the voltage generating circuit 130 to generate the second level of well bias Vwell. The second level is greater than the first level and may be the ground or the positive voltage level.

In operation S660, an operation of applying the program voltage to the selected memory block (e.g., the first memory block BLK1) may be performed.

The operating voltage applying circuit 131 of the voltage generating circuit 130 may generate the program voltage and the pass voltage and may transmit the program voltage and the pass voltage to the global word lines GWL.

The first block decoder 121 of the address decoder 120 may generate and output the first block select signal BLKWL1 having the high potential, and the pass transistors TR_pass of the first pass transistor unit 123 may couple the global word lines GWL and the first local word lines LWL_A of the first memory block BLK1 in response to the first block select signal BRKWL1. Accordingly, the program voltage is applied to the selected local word line among the first local word lines LWL_A, and the pass voltage is applied to the remaining unselected local word lines.

In operation S670, the program verify operation is performed on the selected memory block (e.g., the first memory block BLK1).

The operating voltage applying circuit 131 of the voltage generating circuit 130 may generate the set program verify voltage and pass voltage to transfer to the global word lines GWL. In addition, the well bias applying circuit 132 of the voltage generating circuit 130 may generate and output the well bias Vwell having the first level or the second level set in the operation S640 or the operation S650.

The first block decoder 121 of the address decoder 120 may generate and output the first block select signal BLKWL1 having the high potential, and the pass transistors TR_pass of the first pass transistor unit 123 may couple the global word lines GWL and the first local word lines LWL_A of the first memory block BLK1 in response to the first block select signal BRKWL1. Accordingly, the program verify voltage may be applied to the selected local word line among the first local word lines LWL_A, and the pass voltage may be applied to the remaining unselected local word lines.

The well bias Vwell having the first level or the second level may be applied to the wells of the pass transistors Tr_pass included in the first pass transistor unit 123 and the second pass transistor unit 124 of the address decoder 120, and when the level of the program verify voltage is the lower than the level of the set voltage, the pass transistors TR_pass of the second pass transistor unit 124 corresponding to the memory block (e.g., the second memory block BLK2) not selected by the well bias Vwell having the first level may be prevented from being turned on abnormally. Accordingly, the potential of the global word line from rising due to the potential of the local word line of the unselected memory block may be blocked.

The read and write circuit 140 may sense the potential or the amount of current of the bit lines BL (BL0 to BLk) to determine whether the memory cells coupled to the selected local word line of the selected first memory block BLK1 are normally programmed.

In the embodiment of the present disclosure described above, it is described that the program verify operation is performed by using one program verify voltage. However, when the program verify operation may be performed by using the plurality of program verify voltages, the program verify operation may be performed by applying the well bias Vwell having the first level to the wells of the pass transistors Tr_pass included in the first pass transistor unit 123 and the second pass transistor unit 124 when the program verify voltage lower than the set voltage is applied to the selected memory block.

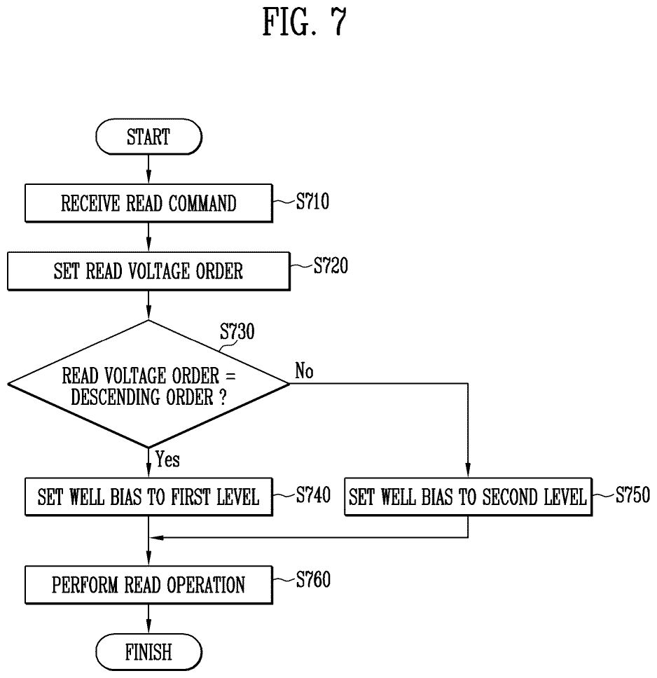

FIG. 7 is a flowchart illustrating a method of operating the memory device 100 according to another embodiment of the present disclosure.

The method of operating the memory device 100 according to another embodiment of the present disclosure will be described below with reference to FIGS. 1 to 4 and 7.

In operation S710, the memory device 100 may receive the read command. In an embodiment, the command CMD and the address ADD corresponding to the read operation may be received from the controller (not shown) outside the memory device 100.

In operation S720, the control circuit 150 may set the read voltage order of sequentially applying the plurality of read voltages in the read operation in response to the command CMD. For example, whether to perform the read operation of sequentially applying the plurality of read voltages in the ascending order from the read voltage having the low level to the high level or in the descending order from the read voltage having the high level to the low level is set.

In operation S730, the control circuit 150 may determine whether the set read voltage order is the descending order.

When the set read voltage order is determined to be the descending order (YES in the operation S730), in operation S740, the control circuit 150 may set the well bias Vwell applied to the wells of the pass transistors Tr_pass included in the first pass transistor unit 123 and the second pass transistor unit 124 included in the address decoder 120 to the first level and may control the voltage generating circuit 130 to generate the well bias VWell having the first level. The first level may be the negative voltage level.

When the set read voltage order is determined to be the ascending order (NO in the operation S730), in operation S750, the control circuit 150 may set the well bias Vwell applied to the wells of the pass transistors Tr_pass included in the first pass transistor unit 123 and the second pass transistor unit 124 included in the address decoder 120 to the second level and may control the voltage generating circuit 130 to generate the well bias VWell having the second level. The second level may be the negative voltage level, the ground level, or the positive voltage level greater than the first level.

In operation S760, the read operation may be performed on the selected memory block (e.g., the first memory block BLK1).

The operating voltage applying circuit 131 of the voltage generating circuit 130 may generate the plurality of read voltages and pass voltages to transfer to the global word lines GWL. In addition, the well bias applying circuit 132 of the voltage generating circuit 130 may generate and output the well bias Vwell having the first level or the second level set in the operation S740 or the operation S750.

The first block decoder 121 of the address decoder 120 may generate and output the first block select signal BLKWL1 having the high potential, and the pass transistors TR_pass of the first pass transistor unit 123 may couple the global word lines GWL and the first local word lines LWL_A of the first memory block BLK1 in response to the first block select signal BRKWL1. Accordingly, the plurality of read voltages are sequentially applied to the selected local word line among the first local word lines LWL_A, and the pass voltage may be applied to the remaining unselected local word lines.

The well bias Vwell having the first level or the second level may be applied to the wells of the pass transistors Tr_pass included in the first pass transistor unit 123 and the second pass transistor unit 124 of the address decoder 120, and when the plurality of read voltages are applied in the descending order, prevented may be abnormal turn on of the pass transistor Tr_pass of the second pass transistor unit 124 corresponding to the memory block (e.g., the second memory block BLK2), which is not selected by the well bias Vwell having the first level.

The read and write circuit 140 may sense the potential or the amount of current of the bit lines BL (BL0 to BLk), the read data stored in the memory cells coupled to the selected local word line of the selected first memory block BLK1, and may output the read data DATA to the outside.

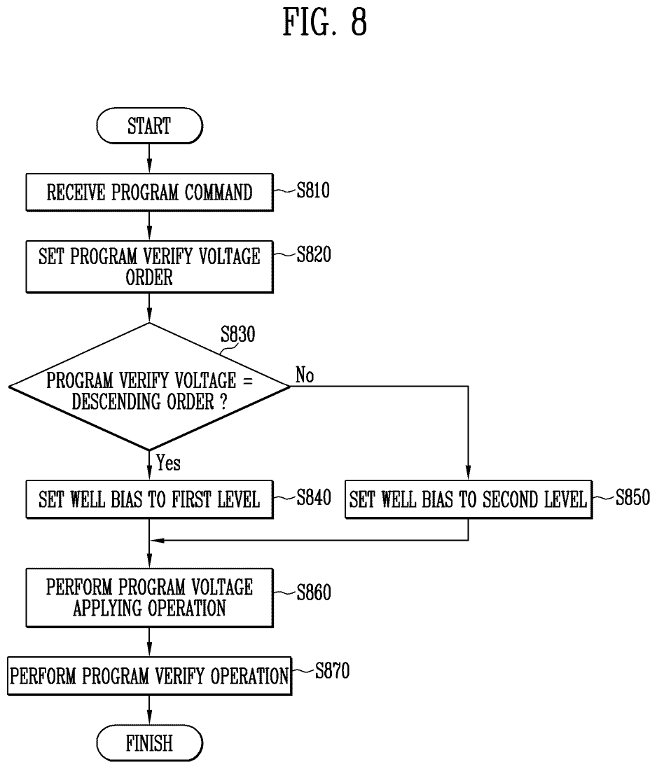

FIG. 8 is a flowchart illustrating a method of operating the memory device 100 according to another embodiment of the present disclosure.

The method of operating a memory device according to another embodiment of the present disclosure will be described below with reference to FIGS. 1 to 4 and 8.

In operation S810, the memory device 100 may receive the program command. In an embodiment, the command CMD, the address ADD, and the data DATA corresponding to the program operation may be received from the controller (not shown) outside the memory device 100.

The read and write circuit 140 may apply the program allowable voltage (e.g., the ground voltage) or the program inhibit voltage (e. g., the power supply voltage) to the bit lines BL0 to BLk based on the received data DATA.

In operation S820, in response to the command CMD, the control circuit 150 may set the program verify voltage order of sequentially applying the plurality of program verify voltages in the program verify operation. For example, whether to perform the program verify operation of sequentially applying the plurality of program verify voltages in the ascending order from the low level of program verify voltage to the high level of program verify or in the descending order from the high level of program verify voltage to the low level of program verify, is set.

In operation S830, the control circuit 150 may determine whether the set program verify voltage order is the descending order.

When the set program verify voltage order is the descending order (YES in the operation S830), in operation S840, the control circuit 150 may set the well bias Vwell applied to the wells of the pass transistors Tr_pass included in the first pass transistor unit 123 and the second pass transistor unit 124 included in the address decoder 120 to the first level, and may control the voltage generating circuit 130 to generate the well bias VWell of the first level. The first level may be the negative voltage level.

When the set program verify voltage order is the ascending order (NO in the operation S830), in operation S850, the control circuit 150 may set the well bias Vwell applied to the wells of the pass transistors Tr_pass included in the first pass transistor unit 123 and the second pass transistor unit 124 included in the address decoder 120 to the second level, and control the voltage generating circuit 130 to generate the well bias VWell of the second level. The second level may be the negative voltage level, the ground level, or the positive voltage level greater than the first level.

In operation S860, an operation of applying the program voltage to the selected memory block (e.g., the first memory block BLK1) may be performed.

The operating voltage applying circuit 131 of the voltage generating circuit 130 generates a program voltage and a pass voltage and transmits the program voltage and the pass voltage to the global word lines GWL.

The first block decoder 121 of the address decoder 120 generates and outputs the high-potential first block select signal BLKWL1, and the pass transistors TR_pass of the first pass transistor unit 123 couple the global word lines GWL and the first local word lines LWL_A of the first memory block BLK1 in response to the first block select signal BRKWL1. Accordingly, a program voltage is applied to a selected local word line among the first local word lines LWL_A, and a pass voltage is applied to the remaining unselected local word lines.

In operation S870, the program verify operation may be performed on the selected memory block (e.g., the first memory block BLK1).

The operating voltage applying circuit 131 of the voltage generating circuit 130 may generate the set program verify voltage and pass voltage and transmit the set program verify voltage and pass voltage to the global word lines GWL. In addition, the well bias applying circuit 132 of the voltage generating circuit 130 may generate and output the well bias Vwell of the first level or the second level set in operation S840 or operation S850 described above.

The first block decoder 121 of the address decoder 120 generates and outputs the first block select signal BLKWL1 at the high potential, and the pass transistors TR_pass of the first pass transistor unit 123 couple the global word lines GWL and the first local word lines LWL_A of the first memory block BLK1 in response to the first block select signal BRKWL1. Accordingly, a program verify voltage is applied to a selected local word line among the first local word lines LWL_A, and a pass voltage is applied to the remaining unselected local word lines.

The well bias Vwell of the first level or the second level is applied to wells of the pass transistors Tr_pass included in the first pass transistor unit 123 and the second pass transistor unit 124 of the address decoder 120.

The read and write circuit 140 may sense the potential or the amount of current of the bit lines BL (BL0 to BLk) to determine whether the memory cells coupled to the selected local word line of the selected first memory block BLK1 are normally programmed.

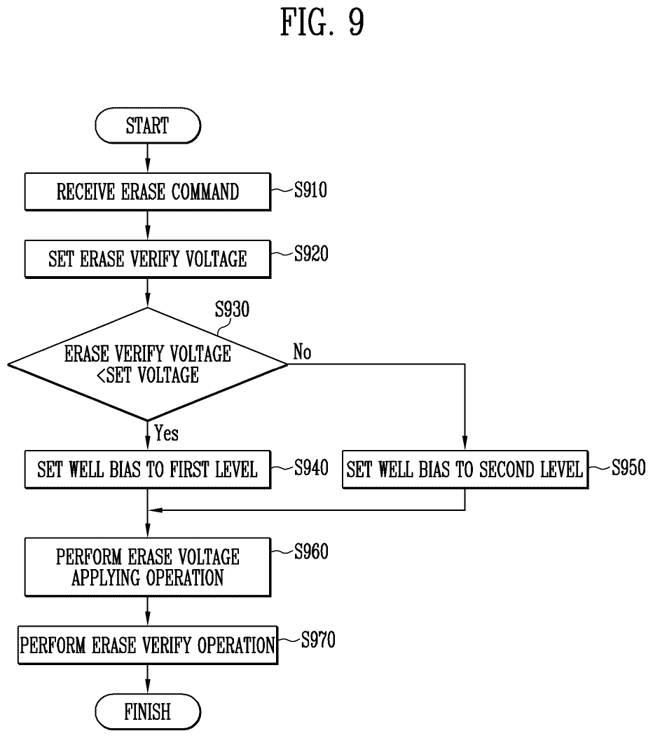

FIG. 9 is a flowchart illustrating a method of operating the memory device 100 according to another embodiment of the present disclosure.

A method of operating the memory device 100 according to another embodiment of the present disclosure will be described below with reference to FIGS. 1 to 4 and 9.

In operation S910, the memory device 100 may receive an erase command. In an embodiment, the command CMD and the address ADD corresponding to the erase operation may be received from the controller (not shown) outside the memory device 100.

In operation S920, the control circuit 150 may set the erase verify voltage to be used during an erase verify operation during an erase operation in response to the command CMD.

In operation S930, the control circuit 150 may determine whether the set erase verify voltage has a potential lower than the set voltage.

In the operation S930, when it is determined that the set erase verify voltage is lower than the set voltage (if YES), in operation S940, the control circuit 150 sets the well bias Vwell applied to the wells of the pass transistors Tr_pass included in the first pass transistor unit 123 and the second pass transistor unit 124 included in the address decoder 120 to the first level, and controls the voltage generating circuit 130 to generate the well bias VWell of the first level. The first level may be the negative voltage level.

In the operation S930, when it is determined that the set erase verify voltage is equal to or greater than the set voltage (if NO), in operation S950, the control circuit 150 may set the well bias Vwell applied to the wells of the pass transistors Tr_pass included in the first pass transistor unit 123 and the second pass transistor unit 124 included in the address decoder 120 to the second level, and may control the voltage generating circuit 130 to generate the second level of well bias Vwell. The second level may be greater than the first level and may be the ground or positive voltage level.

In operation S960, the erase voltage applying operation may be performed on the selected memory block (e.g., the first memory block BLK1). The erase voltage applying operation may be performed in a Gate Induced Drain Leakage (GIDL) method.

The erase voltage may be applied to the source line SL or the bit lines BL of the first memory block BLK1, and the operating voltage applying circuit 131 of the voltage generating circuit 130 may generate the erase operation voltage and may transmit the erase operation voltage to the global drain select line GDSL or the global source select line GSSL.

The first block decoder 121 of the address decoder 120 may generate and output the first block select signal BLKWL1 at the high potential, and the pass transistors TR_pass of the first pass transistor unit 123 couple the global drain select line GDSL or the global source select line GSSL and the drain select line DSL or the source select line SSL of the first memory block BLK1 in response to the first block select signal BRKWL1. Accordingly, GIDL current may be generated in the lower channel of the drain select transistor DST or the source select transistor SST of the first memory block BLK1, and the GIDL current may flow into the channels of the memory strings ST0 to STk.

In operation S970, the erase verify operation may be performed on the selected memory block (e.g., the first memory block BLK1).

The operating voltage applying circuit 131 of the voltage generating circuit 130 may generate the set erase verify voltage and may transmit the generated erase verify voltage to the global word lines GWL. In addition, the well bias applying circuit 132 of the voltage generating circuit 130 may generate and output the well bias Vwell of the first level or the second level set in the operation S940 or the operation S950.

The first block decoder 121 of the address decoder 120 may generate and output the first block select signal BLKWL1 at the high potential, and the pass transistors TR_pass of the first pass transistor unit 123 may couple the global word lines GWL and the first local word lines LWL_A of the first memory block BLK1 in response to the first block select signal BRKWL1. Accordingly, the erase verify voltage may be applied to the first local word lines LWL_A.

The well bias Vwell of the first level or the second level may be applied to the wells of the pass transistors Tr_pass included in the first pass transistor unit 123 and the second pass transistor unit 124 of the address decoder 120, and when the erase verify voltage has a level lower than the set voltage, the pass transistors TR_pass of the second pass transistor unit 124 corresponding to the memory block (e.g., the second memory block BLK2) not selected by the well bias Vwell in the first level may be prevented from being turned on abnormally. Accordingly, the potential of the global word line may be blocked from rising due to the potential of the local word line of the unselected memory block.

The read and write circuit 140 may sense the potential or the amount of current of the bit lines BL (BL0 to BLk) to determine whether the memory cells included in the selected first memory block BLK1 are normally erased.

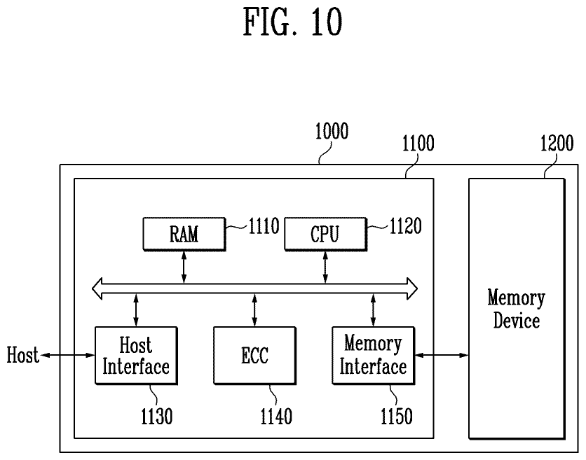

FIG. 10 is a block diagram illustrating a configuration of a memory system 1000 according to an embodiment of the present disclosure.

Referring to FIG. 10, the memory system 1000 according to an embodiment of the present disclosure may include a memory device 1200 and a controller 1100.

The memory device 1200 may be used to store data information having various data types such as text, graphics, software code, and the like. The memory device 1200 may be the memory device described with reference to FIG. 1, and a detailed description thereof will be omitted.

The controller 1100 may be coupled to the host and the memory device 1200 and may be configured to access the memory device 1200 in response to a request from the host. For example, the controller 1100 may be configured to control read, write, erase, and background operations of the memory device 1200.

The controller 1100 may include a RAM (Random Access Memory) 1110, a CPU (Central Processing Unit) 1120, a host interface (Host Interface) 1130, an ECC (Error Correction Code Circuit) 1140, a memory interface (Memory Interface) 1150, and the like.

The RAM 1110 may be used as an operation memory of the CPU 1120, a cache memory between the memory device 1200 and a host, a buffer memory between the memory devices 1200 and the host, or the like. For reference, the RAM 1110 may be replaced with a Static Random Access Memory (SRAM), a Read Only Memory (ROM), or the like.

The CPU 1120 may be configured to control the overall operation of the controller 1100. For example, the CPU 1120 is configured to operate firmware such as a Flash Translation Layer (FTL) stored in the RAM 1110.

The host interface 1130 may be configured to perform interfacing with the host. For example, the controller 1100 communicates with the host through at least one of various communication standards or interfaces such as a Universal Serial Bus (USB) protocol, a MultiMedia Card (MMC) protocol, a Peripheral Component Interconnection (PCI) protocol, a PCI-Express (PCI-E) protocol, an Advanced Technology Attachment (ATA) protocol, a Serial-ATA protocol, a Parallel-ATA protocol a Small Computer System Interface (SCSI) protocol, an Enhanced Small Disk Interface (ESDI) protocol, an Integrated Drive Electronics (IDE) protocol, and a private protocol.

The ECC circuit 1140 may be configured to detect and correct errors included in data read from the memory device 1200 using an error correction code (ECC).

The memory interface 1150 may be configured to perform interfacing with the memory device 1200. For example, the memory interface 1150 may include a NAND interface or a NOR interface.

For reference, the controller 1100 may further include the buffer memory (not shown) for temporarily storing data. The buffer memory may be used to temporarily store data transmitted to the outside through the host interface 1130 or temporarily store data transmitted from the memory device 1200 through the memory interface 1150. In addition, the controller 1100 may further include a ROM for storing code data for interfacing with the host.

As described above, since the memory system 1000 according to an embodiment of the present disclosure includes the memory device 1200 having an improved degree of integration and improved characteristics, the degree of integration and the characteristics of the memory system 1000 may also be improved.

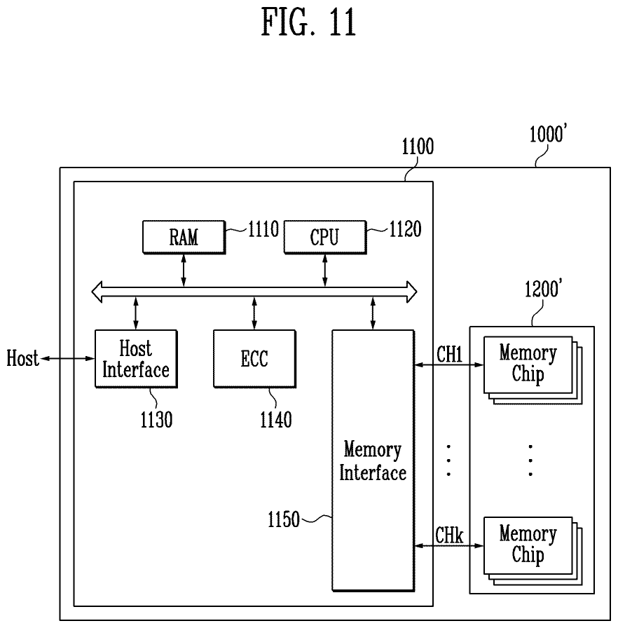

FIG. 11 is a block diagram illustrating a configuration of the memory system 1000 according to an embodiment of the present disclosure. The foregoing descriptions and any overlapping descriptions will be omitted hereafter.

Referring to FIG. 11, a memory system 1000′ according to an embodiment of the present disclosure may include a memory device 1200′ and a controller 1100. In addition, the controller 1100 includes a RAM 1110, a CPU 1120, a host interface 1130, an ECC circuit 1140, a memory interface 1150, and the like.

The memory device 1200′ may be a non-volatile memory, and the memory device 1200′ may be the memory device described above with reference to FIG. 1, and a detailed description thereof will be omitted.

The memory device 1200′ may also be a multi-chip package composed of multiple memory chips. The plurality of memory chips may be divided into a plurality of groups, and the plurality of groups may communicate with the controller 1100 through the first to kth channels CH1 to CHk. In addition, memory chips belonging to one group are configured to communicate with the controller 1100 through a common channel. For reference, the memory system 1000′ may be modified such that one memory chip is coupled to one channel.

As described above, since the memory system 1000′ according to an embodiment of the present disclosure includes the memory device 1200′ having an improved degree of integration and improved characteristics, the degree of integration and the characteristics of the memory system 1000 may also be improved. In particular, by configuring the memory device 1200′ as a multi-chip package, the data storage capacity of the memory system 1000′ may be increased and the driving speed may be improved.

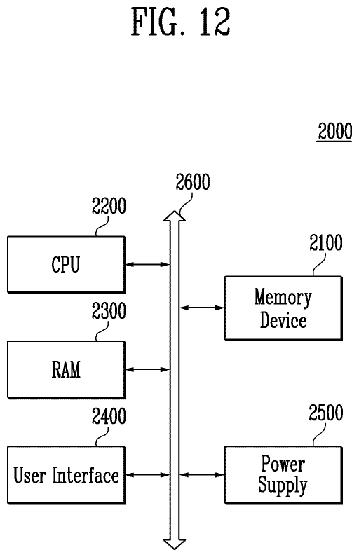

FIG. 12 is a block diagram illustrating a configuration of a computing system 2000 according to an embodiment of the present disclosure. The foregoing descriptions and any overlapping descriptions will be omitted hereafter.

Referring to FIG. 12, the computing system 2000 according to an embodiment of the present disclosure may include a memory device 2100, a CPU 2200, a RAM 2300, a user interface 2400, a power source 2500, a system bus 2600, or the like.

The memory device 2100 may store data provided through the user interface 2400, data processed by the CPU 2200, and the like. In addition, the memory device 2100 may be electrically coupled to the CPU 2200, the RAM 2300, the user interface 2400, the power source 2500, and the like through the system bus 2600. For example, the memory device 2100 may be coupled to the system bus 2600 through a controller (not shown), or may be directly coupled to the system bus 2600. When the memory device 2100 is directly coupled to the system bus 2600, functions of the controller may be performed by the CPU 2200, the RAM 2300, and the like.

The memory device 2100 may be a non-volatile memory, and the memory device 2100 is the memory device described above with reference to FIG. 1, and a detailed description of the memory device 2900 will be omitted.

In addition, the memory device 2100 may be a multi-chip package composed of a plurality of memory chips as described with reference to FIG. 11.

The computing system 2000 having such a configuration may be a computer, a UMPC (Ultra Mobile PC), a workstation, a net-book, a PDA (Personal Digital Assistants), a portable computer, a web tablet, a wireless phone, a mobile phone, a smartphone, an e-book, a PMP (Portable Multimedia Player), a portable game machine, a navigation device, a black box, a digital camera, a three-dimensional television, a digital audio recorder, a digital audio player, a digital picture recorder, a digitized picture player, a digitized video recorder, a digitized video player, a device capable of transmitting and receiving information in a wireless environment, one of various electronic devices constituting a home network, one of various electrical devices constituting a computer network, one of the various electrical devices constituting the telematics network, an RFID device, or the like.

As described above, since the computing system 2000 according to an embodiment of the present disclosure includes the memory device 2100 with improved integration and improved characteristics, the characteristics of the computing system 2000 may also be improved.

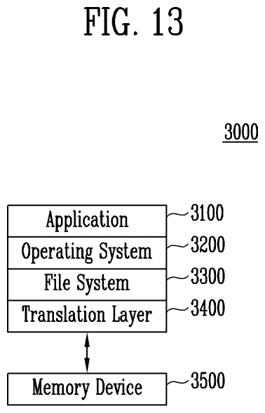

FIG. 13 is a block diagram illustrating a computing system 3000 according to an embodiment of the present disclosure.

Referring to FIG. 13, the computing system 3000 according to an embodiment of the present disclosure may include a software layer including an operating system 3200, an application 3100, a file system 3300, a conversion layer 3400, and the like. The computing system 3000 may also include a hardware layer, such as a memory device 3500.

The operating system 3200 is for managing software, hardware resources, and the like of the computing system 3000, and may control program execution of the central processing unit. The application 3100 is a variety of applications implemented in the computing system 3000 and may be a utility executed by the operating system 3200.

The file system 3300 may refer to a logical structure for managing data and files existing in the computing system 3000, and organizes files or data to be stored in the memory device 3500 according to rules. The file system 3300 may be determined according to the operating system 3200 used in the computing system 3000. For example, if the operating system 3200 is a Windows family of Microsoft, the file system 3300 may be a FAT (File Allocation Table), an NTFS (NT file system), or the like. In addition, if the operating system 3200 is a Unix/Linux family, the file system 3300 may be an extended file system (EXT), a Unix File System (UFS), a Journaling File System (JFS), or the like.

Although the operating system 3200, the application 3100, and the file system 3300 are illustrated as separate blocks in FIG. 13, the application 3200 and the file system 2300 may be included in the operating system 3200.

The translation layer 3400 may translate the address into a form suitable for the memory device 3500 in response to a request from the file system 3300. For example, the translation layer 3400 may convert a logical address generated by the file system 3300 into a physical address of the memory device 3500. The mapping information of the logical address and the physical address may be stored in an address translation table. For example, the translation layer 3400 may be a Flash Translation Layer (FTL), a Universal Flash Storage Link Layer (ULL), or the like.

The memory device 3500 may be a non-volatile memory, and the memory device 3500 is the memory device described above with reference to FIG. 1, and a detailed description thereof will be omitted.

The computing system 3000 with the configuration described above may be divided into an operating system layer performed in a higher level area and a controller layer performed in a lower level area. The application 3100, the operating system 3200, and the file system 3300 are included in the operating system layer and may be driven by an operating memory of the computing system 3000. In addition, the translation layer 3400 may be included in the operating system layer or in the controller layer.

As described above, since the computing system 3000 according to an embodiment of the present disclosure includes the memory device 3500 with improved integration and improved characteristics, the characteristics of the computing system 3000 may also be improved.

According to embodiments of the present disclosure, the reliability of a memory device may be improved by suppressing a level change of an operating voltage applied to a selected word line due to word line noise.

The present invention described above is not limited by the aforementioned embodiments and the accompanying drawings, and it will be apparent to those skilled in the art to which the present disclosure pertains that various replacements, modifications, and changes may be made without departing from the technical scope of the present disclosure. Furthermore, the embodiments may be combined to form additional embodiments.

What is claimed is:

1. A memory device comprising:
a memory cell array including a plurality of memory blocks;
an operating voltage generating circuit configured to generate and apply an operating voltage to global word lines;
a plurality of pass transistor units respectively corresponding to the plurality of memory blocks, respectively configured to couple local word lines of the plurality of memory blocks to the global word lines; and
a well bias applying circuit configured to apply a well bias having a negative level to a well of a plurality of pass transistors included in each of the plurality of pass transistor units when a read voltage, a program verify voltage, or an erase verify voltage to be applied to a selected memory block among the plurality of memory blocks in a read operation, a program verify operation, or an erase verify operation is lower than a set voltage.

2. The memory device of claim 1, wherein the plurality of pass transistors included in an unselected pass transistor unit among the plurality of pass transistor units, the unselected pass transistor unit corresponding to an unselected memory block of the plurality of memory blocks, is configured to prevent a potential of a local word line of the unselected memory block from being transferred to the global word line by the well bias having the negative level.

3. The memory device of claim 1, wherein the well bias applying circuit applies the well bias having a ground or a positive level to the well of the plurality of pass transistors included in each of the plurality of pass transistor units when the read voltage, the program verify voltage, or the erase verify voltage is greater than or equal to the set voltage during the read operation, the program verify operation, or the erase verify operation.

4. The memory device of claim 1, wherein the well bias applying circuit applies the well bias having a first negative level to the well of the plurality of pass transistors when sequentially applying a plurality of read voltages in a descending order from a high level of read voltage to a low level of read voltage in the read operation.

5. The memory device of claim 4, wherein the well bias applying circuit applies the well bias having a second negative level greater than the first negative level, a ground level, or a positive level to the well of the plurality of pass transistors when sequentially applying the plurality of read voltages in an ascending order from the low level of read voltage to the high level of read voltage in the read operation.

6. The memory device of claim 1, wherein the well bias applying circuit applies the well bias having a first negative level to the well of the plurality of pass transistors when sequentially applying a plurality of program verify voltages in a descending order from a high level of program verify voltage to a low level of program verify voltage in the program verify operation.

7. The memory device of claim 6, the well bias applying circuit applies the well bias having a second negative level higher than the first negative level, a ground level, or a positive level to the well of the plurality of pass transistors when sequentially applying the plurality of program verify voltages in an ascending order from the low level of program verify voltage to the high level of program verify voltage in the program verify operation.

8. A method of operating a memory device, the method comprising:
comparing a level of a set voltage with a read voltage to be applied to a selected memory block when performing a read operation;
setting a well bias applied to a well of pass transistors corresponding to the selected memory block and an unselected memory block to a first level when the level of the read voltage is lower than the level of the set voltage;
setting the well bias applied to the well of the pass transistors corresponding to the selected memory block and the unselected memory block to a second level greater than the first level when the level of the read voltage is equal to or greater than the level of the set voltage; and
applying the read voltage to a selected local word line of the selected memory block and applying the well bias having the first level or the second level to the well of the pass transistors.

9. The method of claim 8, wherein the first level is a negative level and the second level is a ground or positive level.

10. The method of claim 8, further comprising:
comparing a level of the set voltage with a program verify voltage to be applied to the selected memory block when performing a program verify operation;
setting the well bias to the first level when the level of the program verify voltage is lower than the level of the set voltage;
setting the well bias to the second level when the level of the program verify voltage is equal to or greater than the level of the set voltage; and
applying the program verify voltage to a selected local word line of the selected memory block and applying the well bias having the first level or the second level to the well of the pass transistors.

11. The method of claim 8, further comprising:
comparing a level of the set voltage with an erase verify voltage to be applied to the selected memory block in an erase verify operation;
setting the well bias to the first level when the level of the erase verify voltage is lower than the level of the set voltage;
setting the well bias to the second level when the level of the erase verify voltage is equal to or greater than the level of the set voltage; and
applying the erase verify voltage to a selected local word line of the selected memory block and applying the well bias having the first level or the second level to the well of the pass transistors.

12. A method of operating a memory device, the method comprising:
setting an order of applying a plurality of read voltages to a selected memory block to a descending order or an ascending order when performing a read operation;
setting a well bias to be applied to a well of pass transistors corresponding to the selected memory block and an unselected memory block to a first level when the order is set to the descending order;
setting the well bias to be applied to the well of the pass transistors corresponding to the selected memory block and the unselected memory block to a second level greater than the first level when the order of applying the plurality of read voltages is set to the ascending order; and
sequentially applying the plurality of read voltages to a selected local word line of the selected memory block in the set descending or ascending order and applying the well bias having the first level or the second level to the well of the pass transistors.

13. The method of claim 12, wherein the first level is a first negative level and the second level is a second negative level greater than the first negative level, a ground level, or a positive level.

14. The method of claim 12, wherein the plurality of read voltages is sequentially applied from a high level of read voltage to a low level of read voltage when the order of applying the plurality of read voltages is set to the descending order.

15. The method of claim 12, wherein the plurality of read voltages is sequentially applied from a low level of read voltage to a high level of read voltage when the order of applying the plurality of read voltages is set to the ascending order.

16. The method of claim 12, further comprising:
setting an order of applying a plurality of program verify voltages to the selected memory block to a verify voltage descending order or a verify voltage ascending order when performing a program verify operation;
setting the well bias to be applied to the well of pass transistors corresponding to the selected memory block and the unselected memory block to the first level when the order of applying the plurality of program verify voltages is set to the verify voltage descending order;
setting the well bias to be applied to the well of the pass transistors corresponding to the selected memory block and the unselected memory block to the second level when the order of applying the plurality of program verify voltages is set to the verify voltage ascending order; and
sequentially applying the plurality of program verify voltages to the selected local word line of the selected memory block in the set verify voltage descending order or the set verify voltage ascending order and applying the well bias having the first level or the second level to the well of the pass transistors.

17. The method of claim 16, wherein the plurality of program verify voltages is sequentially applied from a high level of program verify voltage to a low level of program verify voltage when the order of applying the plurality of program verify voltages is set to the verify voltage descending order.

18. The method of claim 16, wherein the plurality of program verify voltages is sequentially applied from a low level of program verify voltage to a high level of program verify voltage when the order of applying the plurality of program verify voltages is set to the verify voltage ascending order.
